(19) United States
(12) Patent Application Publication
(10) Pub. No.: US 2005/0003307 A1
(43) Pub. Date: Jan. 6, 2005

(54) Method for forming DRAM cell bit-line contact

(76) Inventors: Shih-Fan Kuan, Taoyuan (TW); Kuo-Chien Wu, Miaoli (TW)

Correspondence Address: BIRCH STEWART KOLASCH & BIRCH, PO BOX 747, FALLS CHURCH, VA, 22040-0747, US

(21) Appl. No.: 10/743,135

(22) Filed: Dec. 23, 2003

(30) Foreign Application Priority Data
Jul. 3, 2003 (TW) 92118192

(51) Int. Cl. G03F 7/00

(52) U.S. Cl. 430/313; 430/314; 430/317; 430/319

(57) ABSTRACT

A method for forming DRAM cell bit-line contact is provided. First a dielectric layer is formed on a substrate on which a plurality of control gates has already been formed, and then a patterned photoresist defining a first aperture is formed thereon. Afterwards, through the patterned photoresist the dielectric layer is etched away to expose the substrate there beneath to form the bit-line contact window. Thereafter the bit-line contact windows are filled with a conductive material to form the bit-line contact. Finally, a conductor layer is formed on a previously formed isolation layer, which has a second aperture and the partially exposed bit-line contact, to fill the second aperture.

### FIELD OF THE INVENTION

The present invention relates to a method for forming the bit-line contact of DRAM cell.

### BACKGROUND OF THE INVENTION

DRAM is an essential element in many electronic devices. In the process of fabricating DRAM, an electronic connection between a bit-line and a drain is formed after major elements are formed on a substrate.

To fabricate the electronic connection between the bit-line and the drain, the conventional process is shown in FIG. 1 (a) to (e). The dielectric layer 103, which is made of BPSG, is formed on the substrate 101 having a plurality of control gates 102. Then the isolation layer 109, which is made of TEOS, is formed on the dielectric layer 103.

Further steps include covering the isolation layer 109 with a photoresist 104 defining a contact window pattern 105. Unprotected isolation layer 109 is etched away first with the photoresist 104 being used as a mask, and the etching is complete when the contact window 107 is formed.

As silicon-based integrated circuits shrink, the hole size defined by pattern 105 becomes smaller and smaller, which results in higher aspect ratio or higher vertical anisotropy. As known in the arts, higher vertical anisotropy presents at least two problems. First, expensive instruments are usually required. Secondly, filling a conductive material into the contact window 107 of higher aspect ratio may often cause void.

Besides, when higher vertical anisotropic etching is being performed, the shoulders of control gates 102 may be damaged and a bowl shape 106 appears. Furthermore, the size of contact window 107 formed by etching may not be easily controlled. “Crossfail” is usually caused by over-size width of the contact window 107. Insufficient width of the contact window 107 may cause void or make a drain connection insufficient. Even the prior arts have tried to overcome the problem, complicated methods or expensive instruments are usually employed.

### SUMMARY OF THE INVENTION

One aspect of the present invention provides a method for etching the dielectric layer at lower vertical anisotropy, which reduces the possibility of “crossfail” while forming the bit-line contact of DRAM.

Another aspect of the present invention provides an economical method for etching the dielectric layer at lower vertical anisotropy while forming the bit-line contact of DRAM.

Still another aspect of the present invention provides a method for etching the dielectric layer at lower vertical anisotropy, which prevents the control gates and/or their shoulders from being damaged while forming the bit-line contact of DRAM.

Yet another aspect of the present invention provides a method for etching the dielectric layer at lower vertical anisotropy, which prevents the formation of the void during the filling process of conductive material into the bit-line contact window.

A further aspect of the present invention provides a method for etching the dielectric layer at lower vertical anisotropy with easily-controlled width of contact window.

The present invention includes the following steps. A dielectric layer is formed on the substrate having a plurality of control gates. Then a patterned photoresist is formed on the dielectric layer for defining a first aperture. The isolation layer is etched away with the photoresist, and the etching is complete when a contact window is formed. Next the bit-line contact window is filled with a conductive material for forming a bit-line contact. Then the isolation layer having a second aperture for exposing a portion of the bit-line contact is formed. Filling the second aperture and a conductive layer on the isolation layer is formed.

### BRIEF OF THE DRAWINGS

FIG. 1(a) to FIG. 1(e) are cross-sectional view of the process of the prior art;

FIG. 2 to FIG. 8 are cross-sectional view showing processes of the present invention.

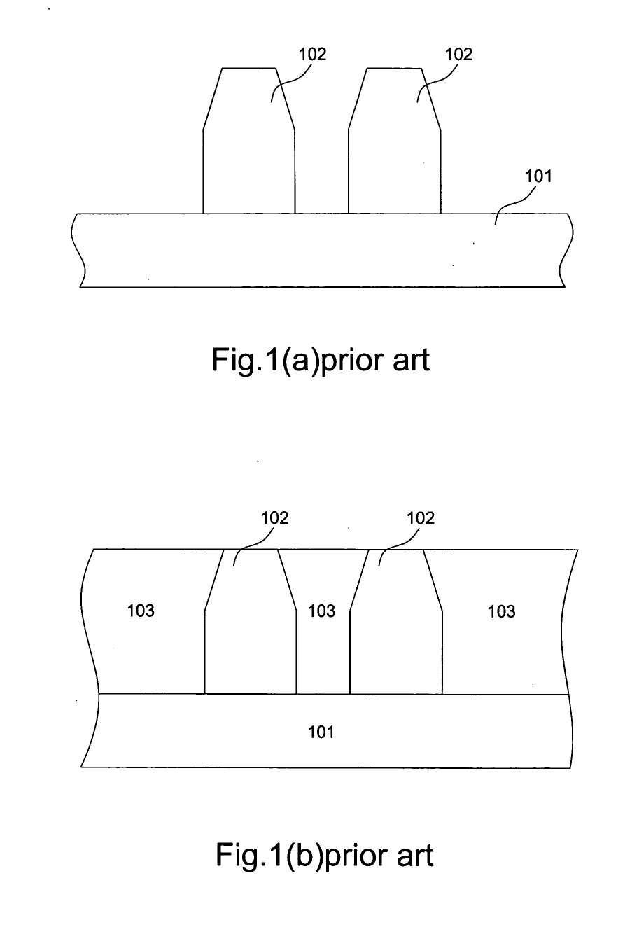

### DETAILED DESCRIPTION OF THE EMBODIMENT

By referring to the Figures and the following illustrations, which are illustrative purpose rather than restrictive, it is expected that the persons skilled in the art may fully understand and utilize the advantages of the present invention. It is noted that some illustrations, elements and/or layers shown in the diagrams may be simplified or even omitted because these are well known to persons skilled in the arts.

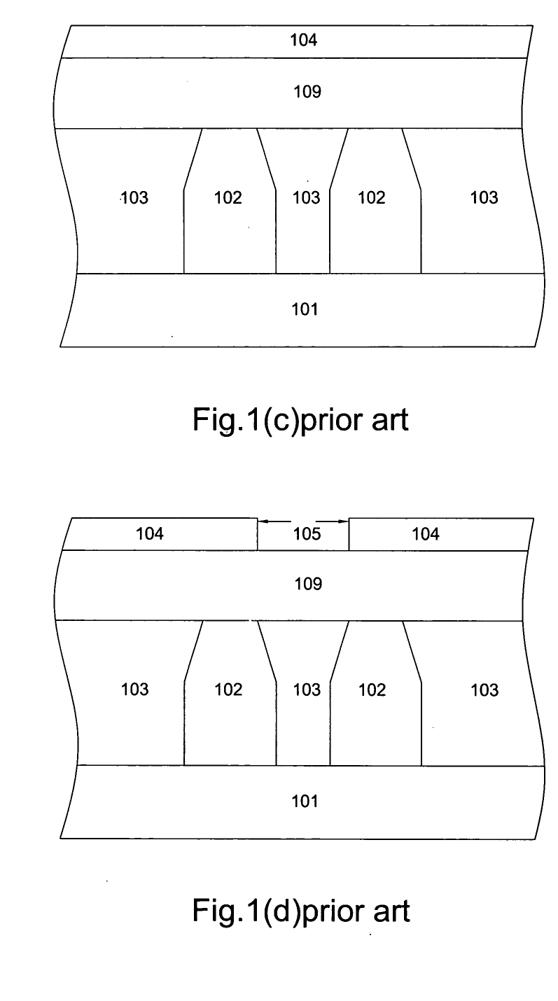

Referring to FIG. 2, a plurality of control gates 202 are formed on the substrate 201 by any method including conventional ones. Substrate 201 is made of silicon preferably and more preferably doped silicon. In addition, the substrate 201 may have a plurality of formed regions or layers that are not shown in FIG. 2. Two control gates 202 in FIG. 2 are used to represent a plurality of control gates.

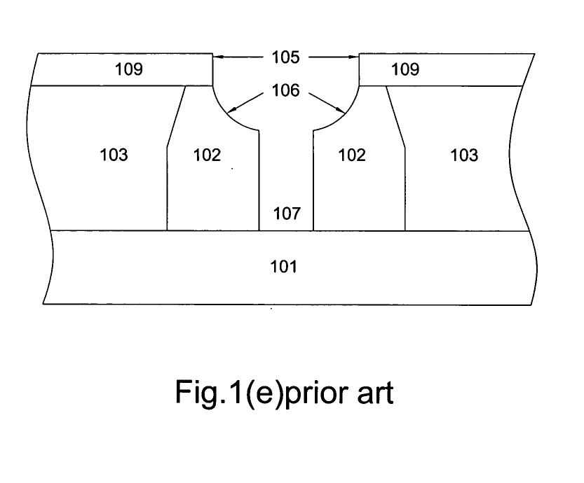

Referring to FIG. 3, the dielectric layer 203, which is made of doped silicon dioxide preferably and more preferably BPSG, is then formed on the substrate 201. Typical process includes the deposition and chemical vapor deposition is preferred. Optionally, the steps further include a first planarization to the dielectric layer 203. Chemical mechanical polishing (CMP) is the preferable process for performing the planarization in this invention.

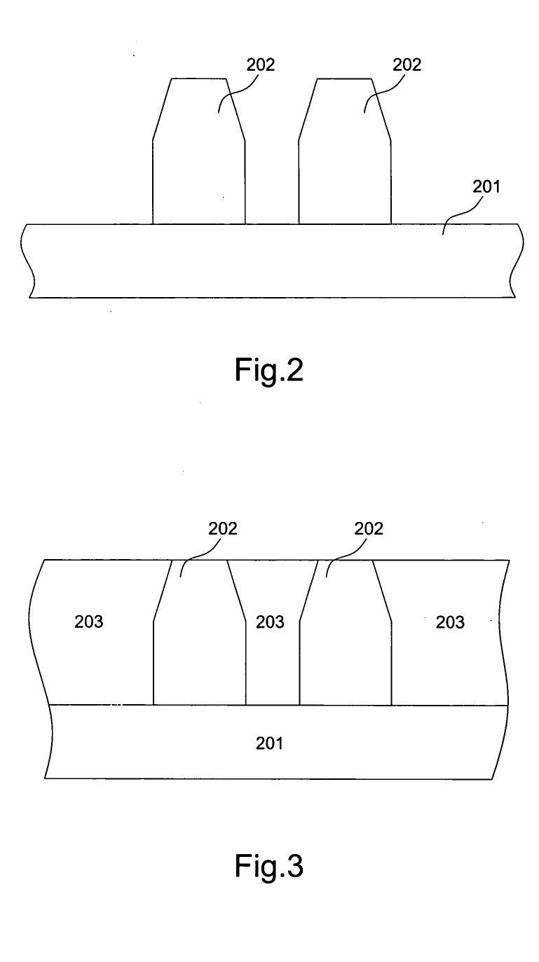

Referring to FIG. 4, a patterned photoresist 204 defining a first aperture 205 is then formed on the dielectric layer 203. Photoresist 204 is preferably a material having substantially lower etching rate than silicon dioxide, and preferably silicon nitride. Preferred process for forming the first aperture 205 after photoresist 204 is formed is the typical etching process.

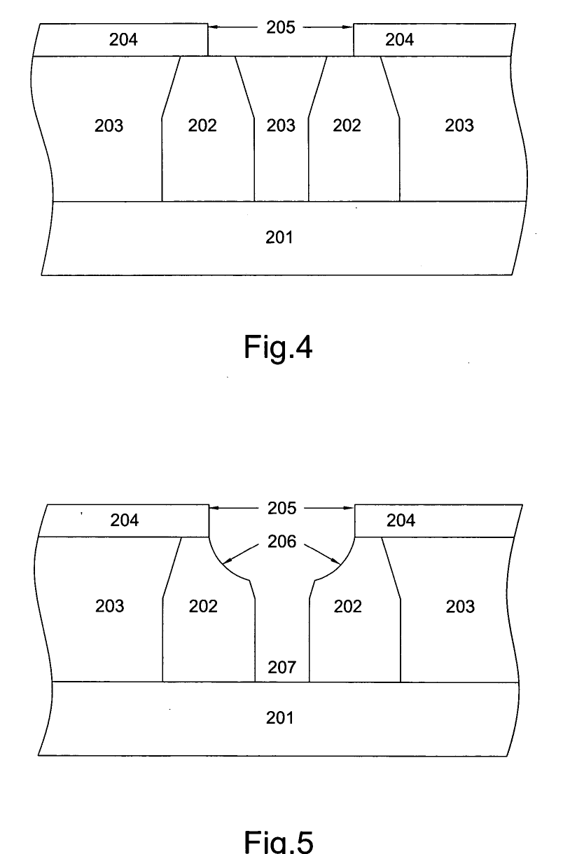

Referring to FIG. 5, the bit-line contact window 207 is then formed by etching the dielectric layer 203 with first aperture 205 being used as a pattern. Since the aspect ratio of contact window 207 of the present invention is lower than the prior art, the width and shape may be easily controlled. So that the damage of shoulder portion, “crossfail” and exposure of control gates associated with the conventional approaches are avoided.

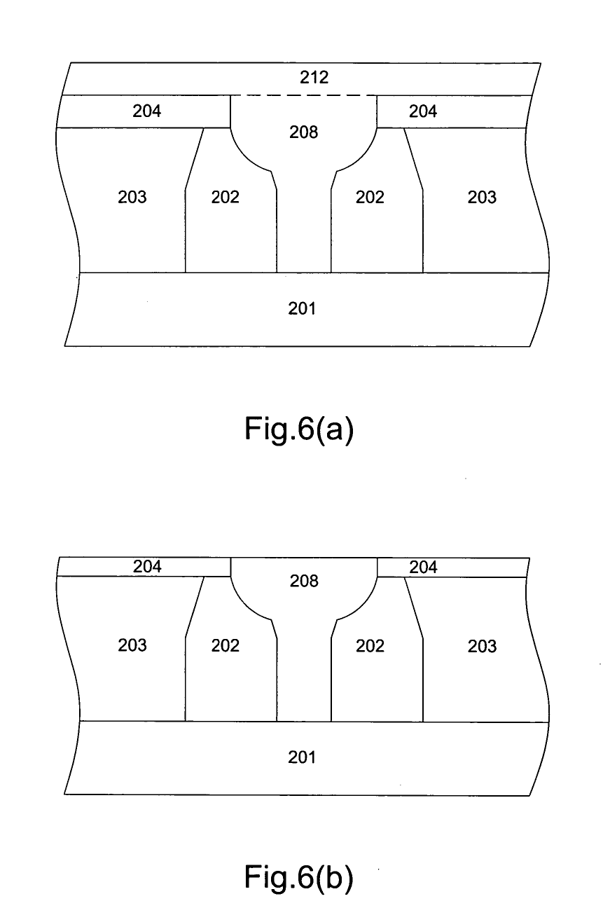

Referring to FIG. 6, the contact window 207 is then filled with a conductive material for forming a bit-line contact 208 and the conductive layer 212 is also formed. The conductive material is preferably a metal or polysilicon, and more preferably is polysilicon or metallic materials having tungsten. The thickness of the conductive layer 212 is not restrictive but thinner is better. The conductive layer 212 is then removed by performing a second planarization, and the photoresist 204 may be removed partially, shown in FIG. 6(b), or completely, shown in FIG. 6(c). A CMP is the most preferable process for planarization.

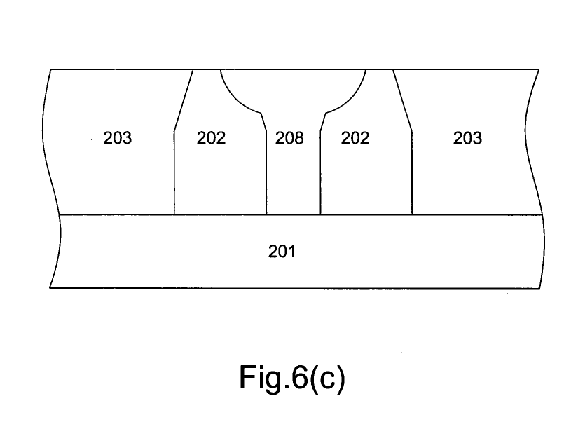

Referring to FIG. 7, after formation of the bit-line contact 208, the isolation layer 209 having a second aperture 210 is formed for exposing a portion of the bit-line contact 208. TEOS is preferred for the isolation layer 209. Etching is the preferable process for forming the second aperture 210.

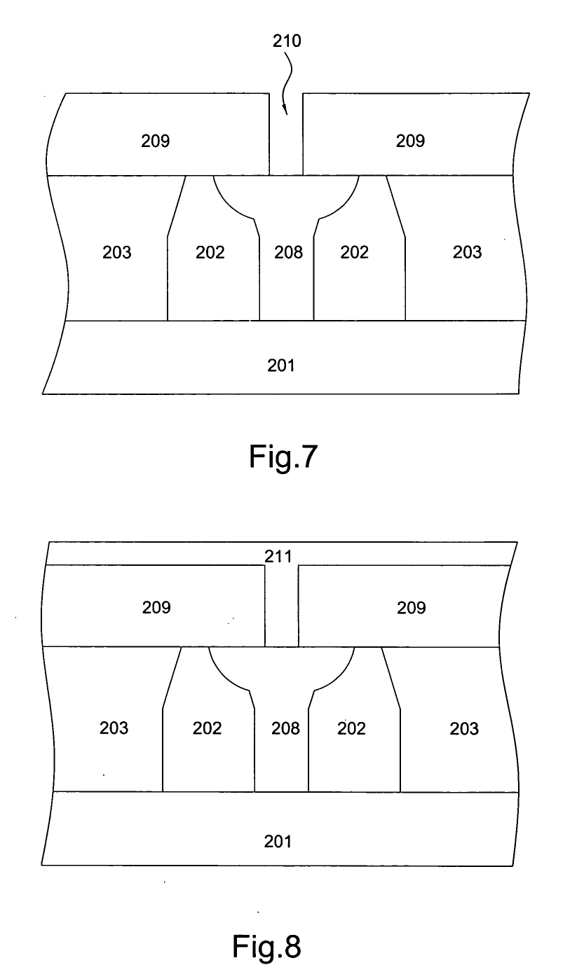

Referring to FIG. 8, the conductive layer 211 is formed and, at the same time, the second aperture 210 is filled with the conductive material. The conductive material is preferably a metal or polysilicon, and more preferably are metallic materials having tungsten or polysilicon. At the end of process shown in FIG. 8, the bit-line contact of DRAM is formed on substrate 201.

By means of the above detailed descriptions of the subject invention, it is the expectation that these above-mentioned illustrations are not intended to be construed in a limiting sense. Instead, it should be well understood that any equivalent variation and equivalent arrangement are covered within the spirit and scope to be protected by the following claims and their equivalences.

1. A method for forming the bit-line contact of DRAM cell, said method comprising the following steps:
A. providing a substrate comprising a plurality of control gates;
B. forming a dielectric layer on said substrate;
C. forming a patterned photoresist defining a first aperture on said dielectric layer;
D. etching said dielectric layer by using said photoresist as a mask for exposing said substrate to form the bit-line contact window;
E. filling said bit-line contact window with a conductive material to form the bit-line contact;
F. forming an isolation layer comprising a second aperture on said dielectric layer to exposure a portion of said bit-line contact; and
G. forming a conductive layer on said isolation layer and filling up said second aperture.

2. The method of claim 1, wherein said dielectric layer is made of BPSG.

3. The method of claim 1, wherein step B further comprises: performing a first planarization to said dielectric layer.

4. The method of claim 3, wherein a CMP process performs said first planarization.

5. The method of claim 1, wherein said photoresist includes silicon nitride.

6. The method of claim 1, wherein said patterned photoresist is formed by etching.

7. The method of claim 1, wherein said step E further comprises forming a conductive layer.

8. The method of claim 1, wherein said conductive material is a polysilicon or a metallic material comprising tungsten.

9. The method of claim 1, wherein said step E further comprises performing a second planarization to said conductive layer and/or said photoresist.

10. The method of claim 9, wherein a CMP process performs said second planarization.

11. The method of claim 9, wherein said second planarization removes a portion of said photoresist.

12. The method of claim 9, wherein said second planarization removes said photoresist completely.

13. The method of claim 1, wherein said isolation layer comprises TEOS.

14. The method of claim 1, wherein said second aperture is obtained by an etching process.

15. The method of claim 1, wherein said conductive layers are made of polysilicon or a metallic material comprising tungsten.
